(19) United States
(12) Patent Application Publication
(10) Pub. No.: US 2020/0235107 A1
(43) Pub. Date: Jul. 23, 2020

(54) ANTIFUSE MEMORY CELLS

(71) Applicant: QUALCOMM Incorporated, San Diego, CA (US)

(72) Inventors: Sinan GOKTEPELI, San Diego, CA (US); George Pete IMTHURN, San Diego, CA (US); Sivakumar KUMARASAMY, San Diego, CA (US)

(21) Appl. No.: 16/742,886

(22) Filed: Jan. 14, 2020

Related U.S. Application Data
(60) Provisional application No. 62/793,856, filed on Jan. 17, 2019.

(51) Int. Cl. H01L 27/112; G11C 17/16; G11C 17/18

(52) U.S. Cl. CPC H01L 27/11206; G11C 17/18; G11C 17/16

(57) ABSTRACT

Antifuse memory cells as well as other applications may provide advantages of conventional approaches. In some examples, a metal backside gate or contact may be formed in the insulator layer opposite the front side contacts and circuits. The metal backside gate or contact may allow a higher voltage on a low resistance and capacitance lie to be applied directly to the dielectric layer of the antifuse to more quickly breakdown the dielectric and program the antifuse.

### CROSS-REFERENCE TO RELATED APPLICATIONS

The present Application for Patent claims the benefit of Provisional Application No. 62/793,856 entitled “ANTIFUSE MEMORY CELLS” filed Jan. 17, 2019, assigned to the assignee hereof, and expressly incorporated herein by reference in its entirety.

### FIELD OF DISCLOSURE

This disclosure relates generally to memory cells, and more specifically, but not exclusively, to antifuse based memory cells.

### BACKGROUND

Silicon-on-insulator (SOI) devices use a layered silicon-insulator-silicon substrate structure as opposed to the more conventional bulk silicon substrate typically used in semiconductor manufacturing. In general, an SOI device consists of a semiconductor substrate on which a thin insulating layer, usually made of silicon dioxide and referred to as the “buried oxide” or “BOX,” layer is formed, e.g., by implantation of oxygen into the bulk silicon substrate. An active region of silicon is formed on the BOX layer. The active silicon layer includes circuit elements of an integrated circuit (IC), e.g., transistors and diodes.

One advantage of isolating the circuitry of the active layer from the bulk semiconductor substrate using the buried oxide layer is a decrease in parasitic capacitance, which improves performance, e.g., provides increased device speed and reduced power usage. Because of these advantages, SOI structures are desirable for high frequency applications such as radio frequency (RF) communication circuits.

In a conventional SOI structure, the SOI structure includes a substrate layer, an insulator layer (BOX), and an active layer. The substrate layer is typically a semiconductor material such as silicon. The insulator layer is a dielectric which is often silicon dioxide formed through the oxidation of a portion of the substrate layer where the substrate layer is silicon. The active layer includes an active device layer and a metallization or metal interconnect layer. The active layer further includes a combination of dopants, dielectrics, polysilicon, metal wiring, passivation, and other layers, materials or components that are present after circuitry has been formed therein. The circuitry may include metal wiring (e.g. in the metal interconnect layer), passive devices such as resistors, capacitors, and inductors, and active devices such as a transistor (e.g., in the active device layer). One issue that may arise with SOI devices is relatively high leakage in the devices of the active layer. In order to compensate for such leakage, a higher threshold voltage (Vt) may be necessary. However, a high Vt may limit the devices' performance and speed.

High volume programmable read only memory (PROM) is needed in RF applications to enable programming of parts to customer needs, tune modules, and improve yields. Existing solutions include poly fuses, but they take a very large area, and antifuses. However, conventional antifuses have certain drawbacks. For example, use of a passgate transistor in the antifuse may allow the leakage from the pass gate to raise the voltage at node A (node between the passgate and antifuse) and will cause the antifuse capacitor to fail. In another example, a transistor is used as the antifuse to bypass this issue. However, this option enables the source of the antifuse transistor at node B (node after antifuse) to pull down the voltage of node A when it is not being programmed. Alternatively, a second transistor may be used as a protection device for the antifuse capacitor. This reduces the leakage and creates a capacitive voltage division. As a result, when the Bitline (BL) is pulsed, there is less of a high transient voltage on the antifuse.

Accordingly, there is a need for systems, apparatus, and methods that overcome the deficiencies of conventional approaches including the methods, system and apparatus provided hereby.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, a memory device comprises: an oxide layer; a pass transistor on a front side of the oxide layer; an antifuse device on the front side of the oxide layer proximate to the pass transistor; a pass transistor gate on a backside of the oxide layer; and an antifuse gate on the front side of the oxide layer.

In another aspect, a memory device comprises: an oxide layer; means for switching a signal on a front side of the oxide layer; means for creating a conductive path on the front side of the oxide layer proximate to the means for switching; a pass transistor gate on a backside of the oxide layer; and an antifuse gate on the front side of the oxide layer.

In still another aspect, a memory device comprises: a pass transistor on a first portion of the memory device; an antifuse device on a second portion of the memory device opposite the first portion; a pass transistor gate on a back side of the memory device; an antifuse gate on a front side of the memory device opposite the backside side; and a bias gate on the back side of the memory device proximate to the pass transistor gate.

In still another aspect, a memory device comprises: means for switching a signal on a first portion of the memory device; means for creating a conductive path on a second portion of the memory device opposite the first portion; a pass transistor gate on a back side of the memory device; an antifuse gate on a front side of the memory device opposite the back side; and means for biasing on the back side of the memory device proximate to the pass transistor gate.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates a side view of an exemplary antifuse in accordance with some examples of the disclosure;

FIG. 2 illustrates a top view of the exemplary antifuse of FIG. 1 in accordance with some examples of the disclosure;

FIG. 3 illustrates an exemplary antifuse with backside protection bias gate in accordance with some examples of the disclosure;

FIG. 4 illustrates an exemplary antifuse capacitor with a backside protection bias gate in accordance with some examples of the disclosure;

FIG. 5 illustrates a top view of the exemplary antifuse capacitor of FIG. 4 in accordance with some examples of the disclosure;

FIG. 6 illustrates a schematic of the antifuse of FIG. 4 in accordance with some examples of the disclosure;

FIG. 7 illustrates an exemplary antifuse capacitor without a backside protection bias gate in accordance with some examples of the disclosure;

FIG. 8 illustrates a schematic of the antifuse of FIG. 7 in accordance with some examples of the disclosure;

FIGS. 9-12 illustrate a schematic of the antifuse memory cell layout of bias conditions for the antifuse of FIG. 4 in accordance with some examples of the disclosure;

FIG. 13 illustrates an exemplary antifuse with back side contact in accordance with some examples of the disclosure;

FIGS. 14-17 illustrates an exemplary layout for the antifuse with back side contact of

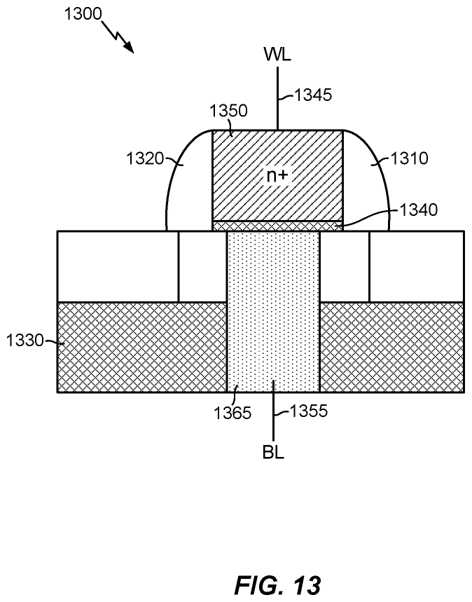

FIG. 13 in accordance with some examples of the disclosure;

FIG. 18 illustrates an exemplary antifuse with backside contact and passgate in accordance with some examples of the disclosure; and

FIG. 19 illustrates an exemplary antifuse with backside contact and passgate on same diffusion island in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein mitigate shortcomings of the conventional methods, apparatus, and systems, as well as other previously unidentified needs. In some examples, a backside metal layer is used as the passgate transistor gate in a memory device. This will ensure that the passgate dielectric can handle more than 10V ensuring the ability to use a high voltage on BL and better damage to the antifuse gate dielectric and more simplified layout and bias circuitry. In other examples, a backside bias is used to ensure the antifuse is protected. The use of a backside pass gate may increase the threshold voltage (Vt) and reduce the leakage that could result in unintended programming. In addition, the use of an antifuse protection bias, similar to a write support bias, creates a field that increases the potential in the antifuse body and protects the antifuse along with providing a smaller solution than conventional approaches. In still other examples, the use of a backside contact to form an antifuse removes that need for a pass gate creating a very small antifuse cell with simplified layout and bias circuitry. It should be understood that a metal backside or gate structure described herein may be composed of polysilicon, copper, tungsten, aluminum, cobalt, or other similar material.

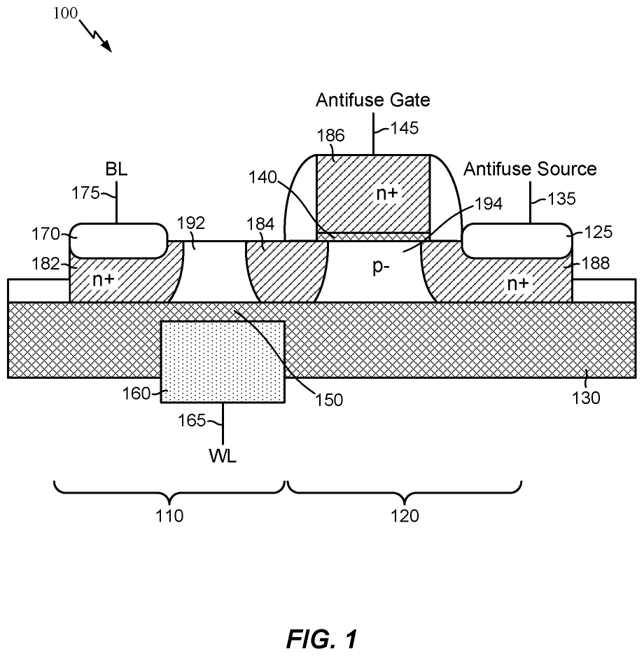

FIG. 1 illustrates a side view of an exemplary antifuse in accordance with some examples of the disclosure. As shown in FIG. 1, an antifuse cell 100 (e.g., a memory device) may include a passgate transistor 110 (i.e., a pass transistor) and an antifuse device 120. The antifuse cell 100 may include an oxide layer 130 (e.g., buried oxide layer), an antifuse source 135 coupled to a first contact 125, a first dielectric layer 140 of an antifuse gate 145, a second dielectric layer 150 of the passgate gate 165 above a backside metal 160 on a first side (backside) of the oxide layer 130. The first dielectric 140 may be approximately 8-25 angstroms thick while the second dielectric 150 may be ten times thicker at approximately 80-250 angstroms. The antifuse cell 100 may also include a second contact 170 coupled to a source 175 for the passgate transistor 110 (e.g., a BL). The second side (e.g., front side opposite the backside) of the antifuse cell 100 may also include a first doping region 182, a second doping region 184, and a third doping region 186, a fourth doping region 188, a first diffusion region 192, and a second diffusion region 194. The use of a backside metal layer (backside metal 160) as the passgate transistor gate may ensure that the passgate dielectric 150 can handle more than 10V. This may ensure the ability to use a high voltage on the passgate source 175 (BL) to cause better damage to the antifuse gate dielectric 140.

In a write operation, the antifuse cell 100 may have an initial condition with all sources and nodes at ground voltage. In the next stage, setup, the antifuse cell 100 may impose 5 v on the source 175 for the passgate (BL, the passgate transistor 110 will have a thick enough second dielectric layer 150 to handle the 5 v). Then, in the programming phase, the antifuse cell 100 may impose a pulse of 5-10 v on the passgate gate 165 to breakdown the first dielectric layer 140 and program the antifuse cell 100. In a read operation, a bias voltage of approximately 1.2 v (Vcore, typical system voltage) may be imposed on the antifuse gate 145. Then the current from the antifuse source 135 may be measured to determine the value of the cell. For example, if no current then the cell 100 is a zero. If a current is detected, the cell 100 is a one.

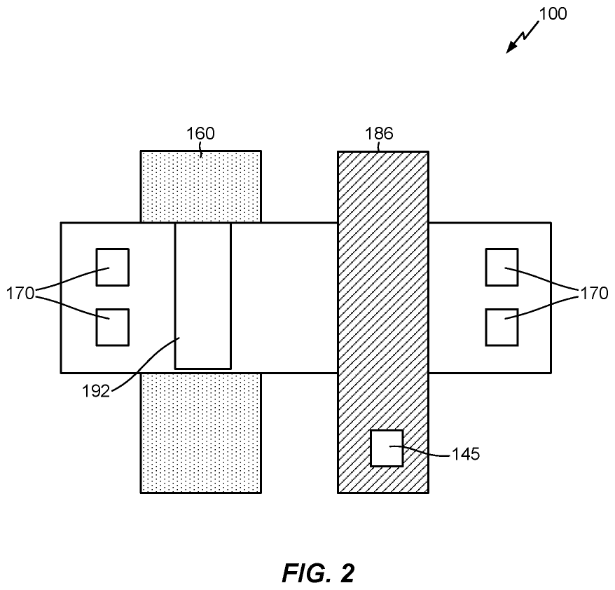

FIG. 2 illustrates a top view of the exemplary antifuse of FIG. 1 in accordance with some examples of the disclosure. As shown in FIG. 2, the antifuse cell 100 may include a plurality of second contacts 170 on a doping region, a backside metal 160 for the passgate transistor 110 under the doping region, a first diffusion region 192, the third doping region 186, an antifuse gate 145 on the third doping region 186, and a plurality of first contacts 125 on the doping region. The first contacts 125 may be coupled a source for antifuse 120.

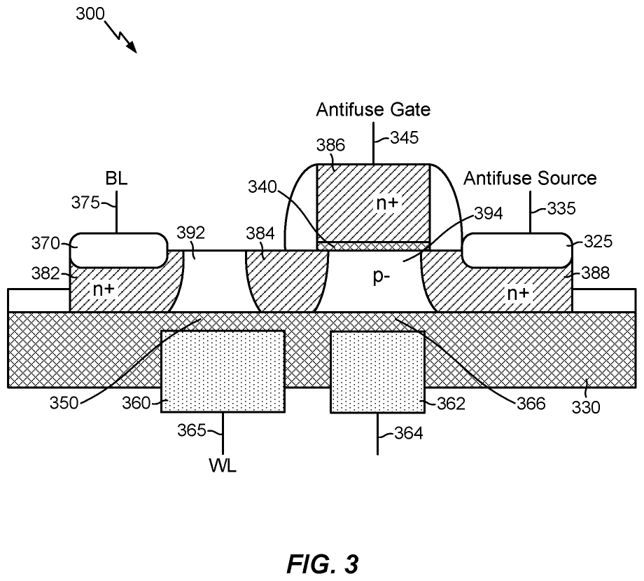

FIG. 3 illustrates an exemplary antifuse with backside protection bias gate in accordance with some examples of the disclosure. As shown in FIG. 3, an antifuse cell 300 (e.g., a memory device) may include a passgate transistor 310 and an antifuse 320. The antifuse cell 300 may include an oxide layer 330 (e.g., buried oxide layer), an antifuse source 335 coupled to a first contact 325, a first dielectric layer 340 of an antifuse gate 345, a second dielectric layer 350 of the passgate gate 365 above a backside metal 360 on a first side (backside) of the oxide layer 330. The first dielectric 340 may be approximately 8-25 angstroms thick while the second dielectric 350 may be ten times thicker at approximately 80-250 angstroms and capable of handling approximately 50 amps of current. This may allow more reliable programming with very high margins and low risk at reading. The antifuse cell 300 may also include a second contact 370 coupled to a source 375 for the passgate 330 (e.g., a BL). The second side (e.g., front side opposite the backside) of the antifuse cell 300 may also include a first doping region 382, a second doping region 384, and a third doping region 386, a fourth doping region 388, a first diffusion region 392, and a second diffusion region 394. The use of a backside metal layer (backside metal 360) as the passgate transistor gate may ensure that the passgate dielectric 350 can handle more than 30V. This may ensure the ability to use a high voltage on the passgate source 375 (BL) to cause better damage to the antifuse gate dielectric 340. The antifuse 300 may also include a means to protect the antifuse cell 300 during a write of other cells, such as a protection bias 364 to provide additional protection. The protection bias 364 may include a backside metal 362 embedded in the oxide layer 130 and a third dielectric 366 similar to the second dielectric 350. By biasing the antifuse transistor protection bias 364 positively during programming would enable higher leakage and prevent charge build-up that could allow the device to fail. It should be understood that the front-gate could also be biased.

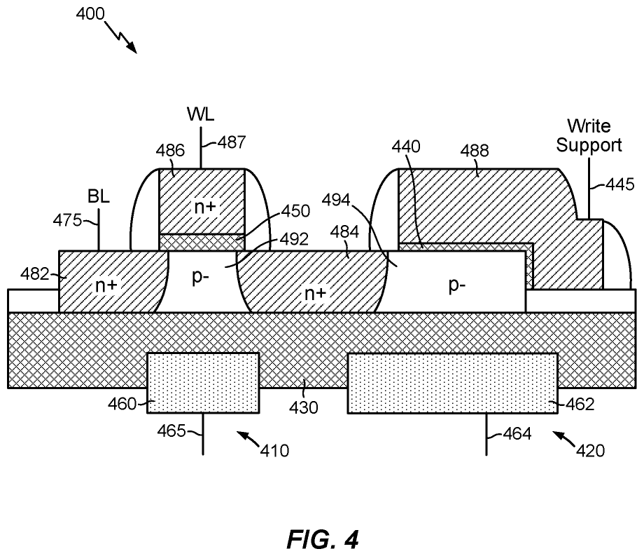

FIG. 4 illustrates an exemplary antifuse capacitor with a backside protection bias gate in accordance with some examples of the disclosure. As shown in FIG. 4, an antifuse cell 400 (e.g., a memory device) may include a passgate transistor 410 and an antifuse capacitor 420. The antifuse cell 400 may include an oxide layer 430 (e.g., buried oxide layer), write support 445, a first dielectric layer 440 of the antifuse capacitor 420, and a second dielectric layer 450 of the passgate 410 above a backside metal 460 on a first side (backside) of the oxide layer 430. The first dielectric 440 may be approximately 8-25 angstroms thick while the second dielectric 450 may be ten times thicker at approximately 80-300 angstroms. This may allow more reliable programming with very high margins and low risk at reading. The antifuse cell 400 may also include a source 475 for the passgate 410 (e.g., a BL), a backside bias source 465, and a source 487 (e.g., word line (WL) for the polysilicon). The second side (e.g., front side opposite the backside) of the antifuse cell 400 may also include a first doping region 482, a second doping region 484, and a third doping region 486, a fourth doping region 488, a first diffusion region 492, and a second diffusion region 494. The use of a backside metal layer (backside metal 460) to bias the antifuse cell 400 may ensure that the antifuse cell 400 is protected by backside bias that is used to increase the Vt and reduce leakage that could result in unintended program. The antifuse cell 400 may also include a protection bias 464 coupled to another backside metal 462 to bias the antifuse capacitor 420 by creating a field that increase the potential in the antifuse body and the protects the antifuse cell 400 while having a smaller footprint (similar to write support bias). Alternatively, Adding an LDD implant in the dielectric 440 would generate an additional electric field at the corner of the dielectric but may reduce the effectiveness of the protection bias. Alternatively, the second diffusion region 494 may be n-doped. Using an n-doped body would make it easier to move carriers to the antifuse dielectric 440. However, this may remove the protection against erroneous write “1” provided by the pn junction of the p-body. It should be understood that different antifuse body doping and dielectric doping, the resulting n- or p-body might prove to be more effective for a given process flow.

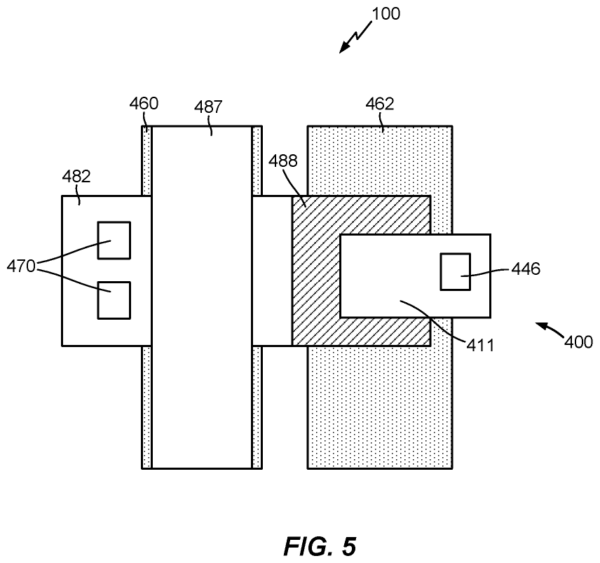

FIG. 5 illustrates a top view of the exemplary antifuse capacitor of FIG. 4 in accordance with some examples of the disclosure. As shown in FIG. 5, the antifuse cell 400 may include a plurality of second contacts 470 on the first doping region 482, a polysilicon gate 487, a backside metal 460 for the passgate 410 under the first doping region 482, another backside metal 462 for protection bias, a contact 446 for the write support 445 on the polysilicon 411 of the antifuse capacitor 410, and a no LDD diffusion region 488 with a large area for dielectric 440 break down.

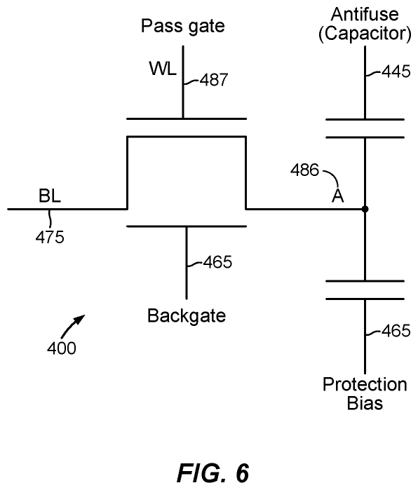

FIG. 6 illustrates a schematic of the antifuse of FIG. 4 in accordance with some examples of the disclosure. As shown in FIG. 6, an antifuse cell 400 may include a passgate 487 coupled between a reading node 489 and a BL 475, an antifuse capacitor 445 and a protection bias 464 after the reading node 489. The leakage on the passgate transistor 487 can further be reduced by using the back gate 465 to increase its Vt.

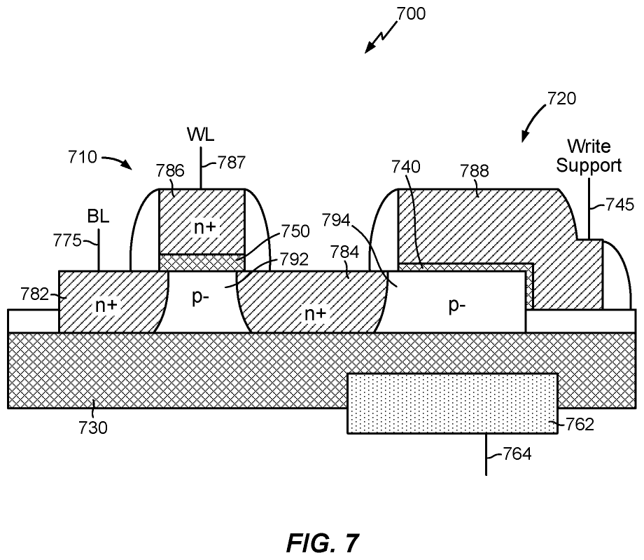

FIG. 7 illustrates an exemplary antifuse capacitor without a backside protection bias gate in accordance with some examples of the disclosure. As shown in FIG. 7, an antifuse cell 700 (e.g., a memory device) may include a passgate transistor 710 and an antifuse capacitor 720. The antifuse cell 700 may include an oxide layer 730 (e.g., buried oxide layer), write support 745, a first dielectric layer 740 of the antifuse capacitor 720, a second dielectric layer 750 of the passgate 710. The first dielectric 740 may be approximately 8-25 angstroms thick while the second dielectric 750 may be ten times thicker at approximately 80-250 angstroms and capable of handling approximately 50 amps of current. This may allow more reliable programming with very high margins and low risk at reading. The antifuse cell 700 may also include a source 775 for the passgate 710 (e.g., a BL), and a source 787 (e.g., word line (WL) for the polysilicon). The second side (e.g., front side opposite the backside) of the antifuse cell 700 may also include a first doping region 782, a second doping region 784, and a third doping region 786, a fourth doping region 788, a first diffusion region 792, and a second diffusion region 794. The antifuse cell 700 may also include a protection bias 764 coupled to a backside metal 762 to bias the antifuse capacitor 720 by creating a field that increase the potential in the antifuse body and the protects the antifuse cell 700 while having a smaller footprint (similar to write support bias).

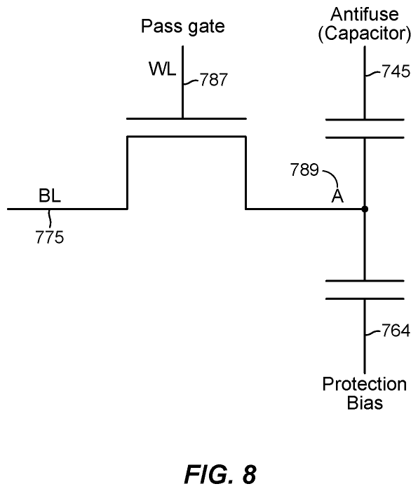

FIG. 8 illustrates a schematic of the antifuse of FIG. 7 in accordance with some examples of the disclosure. As shown in FIG. 8, an antifuse cell 700 may include a passgate 487 coupled between a reading node 789 and a BL 775, an antifuse capacitor 745 and a protection bias 764 after the reading node 789.

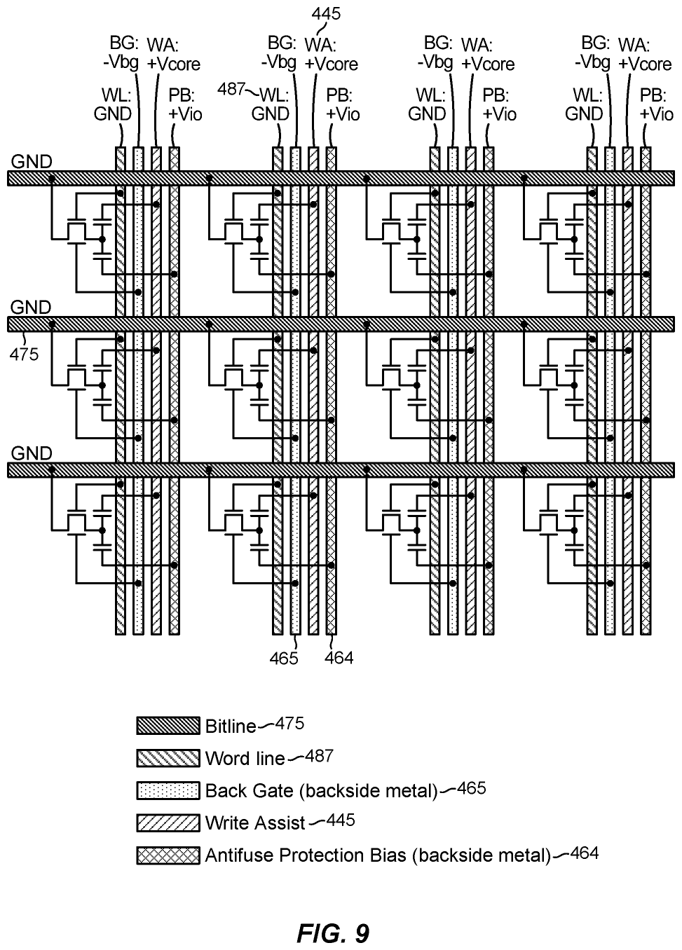

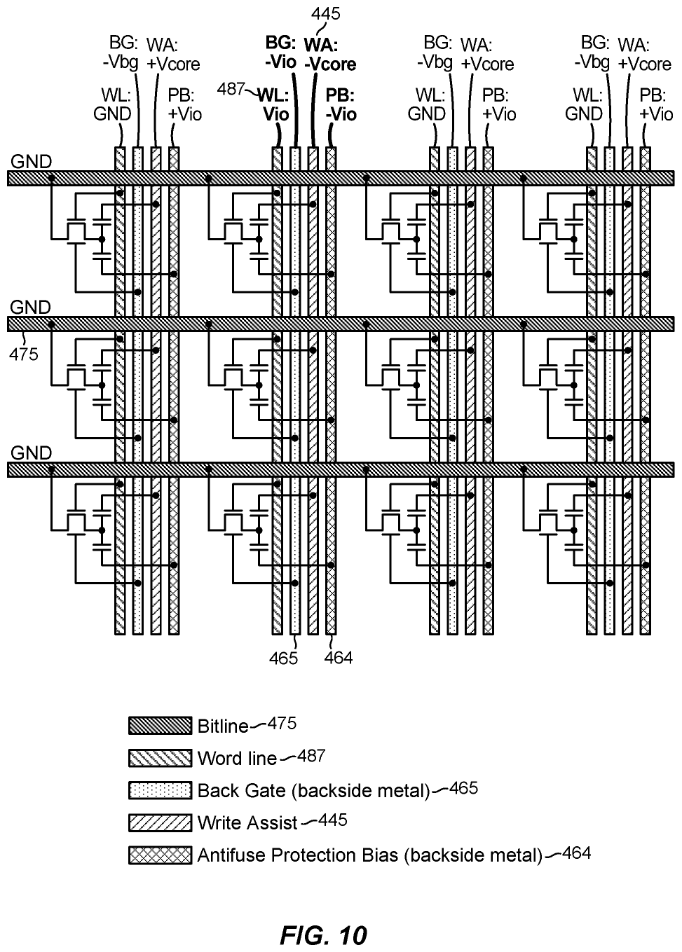

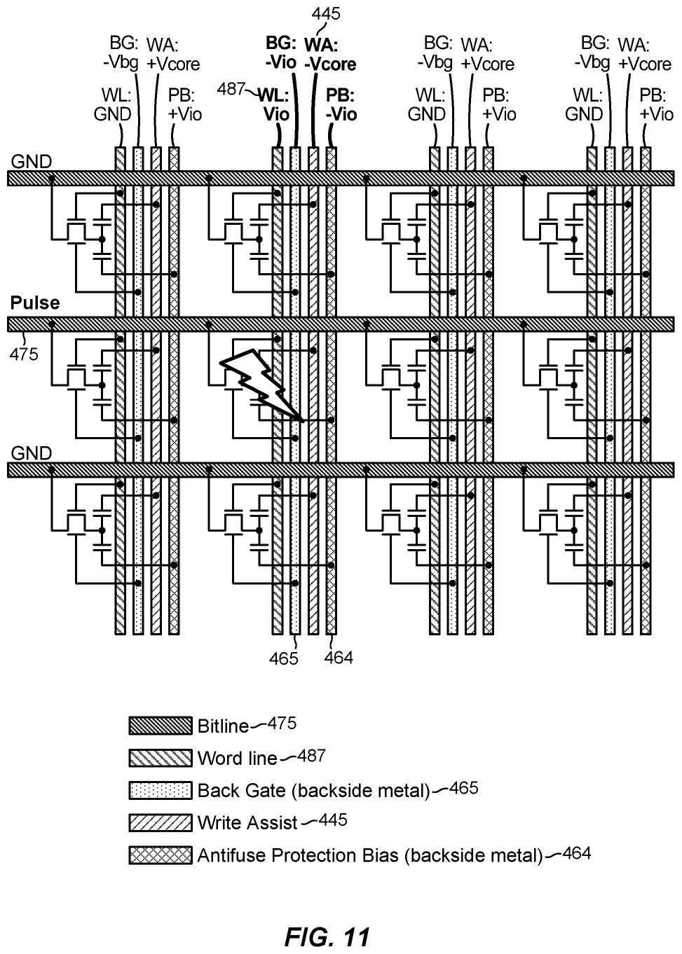

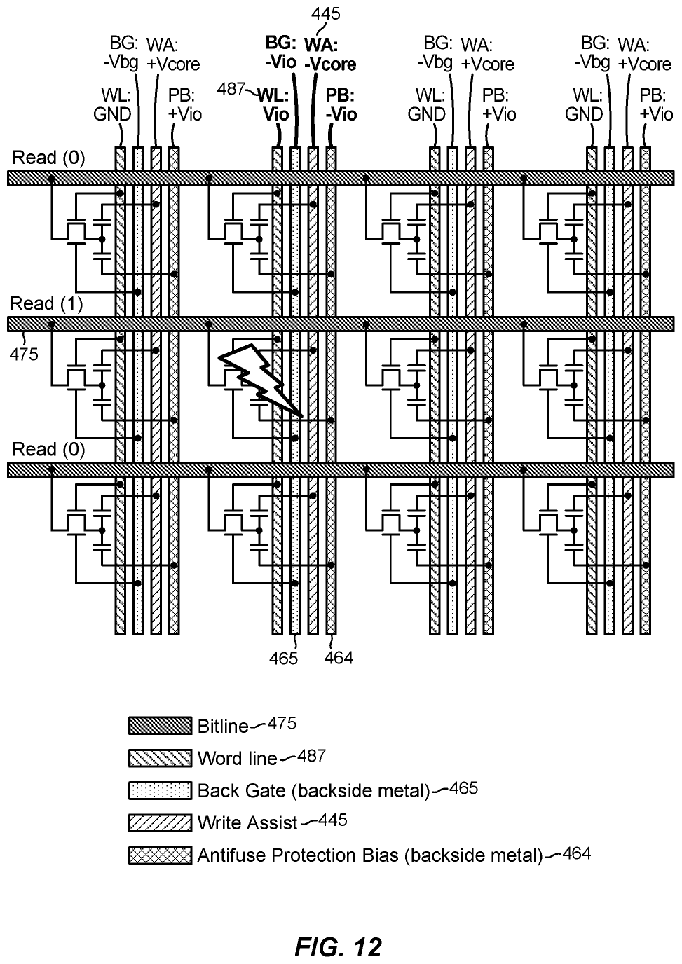

FIGS. 9-12 illustrate a schematic of the antifuse memory cell layout of bias conditions for the antifuse of FIG. 4 in accordance with some examples of the disclosure. As shown in FIG. 9, a write process for the antifuse cell 400 may begin with initial conditions of the BL 475 and WL 487 at ground, the back gate 465 at −Vbg, the write assist 445 at +Vcore, and the protection bias 464 at +Vio. As shown in FIG. 10, the write process may change the WL 487 to +Vio, the back gate 465 to +Vio, the write assist 445 at −Vcore, and the protection bias 464 at −Vcore. As shown in FIG. 11, in the write “1” scenario, the BL 475 may be subject to 1-100 microsecond pulses (Vio or another high programming bias), the WL 487 is at +Vio, the back gate 465 is at +Vio, the write assist 445 is at −Vcore, and the protection bias 464 is at −Vio. During the pulse, the other cells on the same row (seeing the pulse) are protected by their respective positive bias and by the protection bias that reduces the electric field at the antifuse. During the read process of FIG. 12, all are set to ground when not read. At word setup, the back gate 465 is at ground, the write assist 445 is at +Vcore, and the protection bias 464 is at +Vcore. At reading, the WL 487 is at +Vio and the current is sensed in the BL 475 to determine the cell status (one or zero).

FIG. 13 illustrates an exemplary antifuse with back side contact in accordance with some examples of the disclosure. As shown in FIG. 13, an antifuse cell 1300 (e.g., a memory device) may include an oxide layer 1330 (e.g., buried oxide layer), an antifuse source 1345 (e.g., WL), a first dielectric layer 1340 of the antifuse gate 1355 (e.g., BL), a first spacer 1310 and a second spacer 1320 around a first doped region 1350, and a backside metal 1365. This may ensure that there is a means for a high voltage pulse to a gate dielectric 1340 through a low resistance and capacitance line of backside metal 1365, which may avoid the need for additional passgate and other protection circuits.

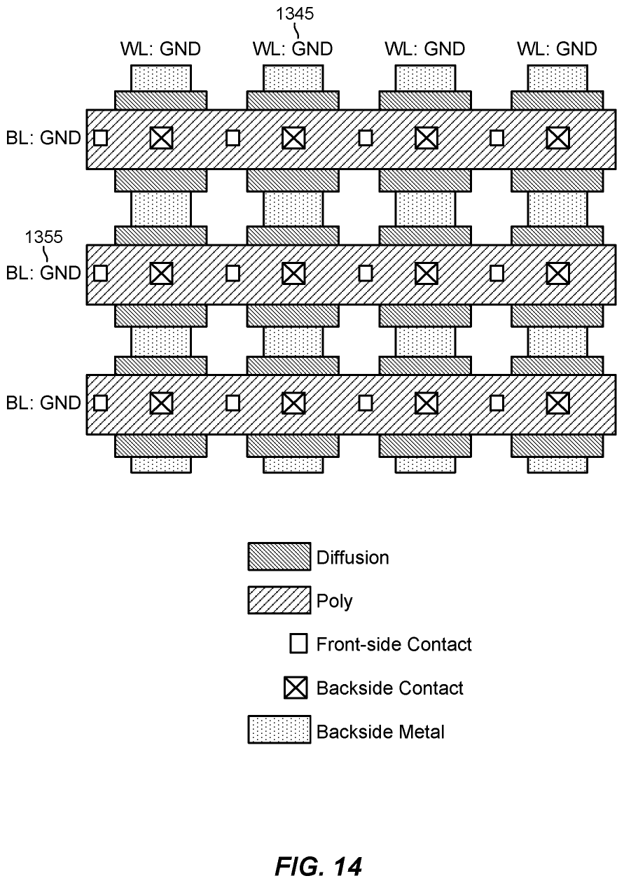

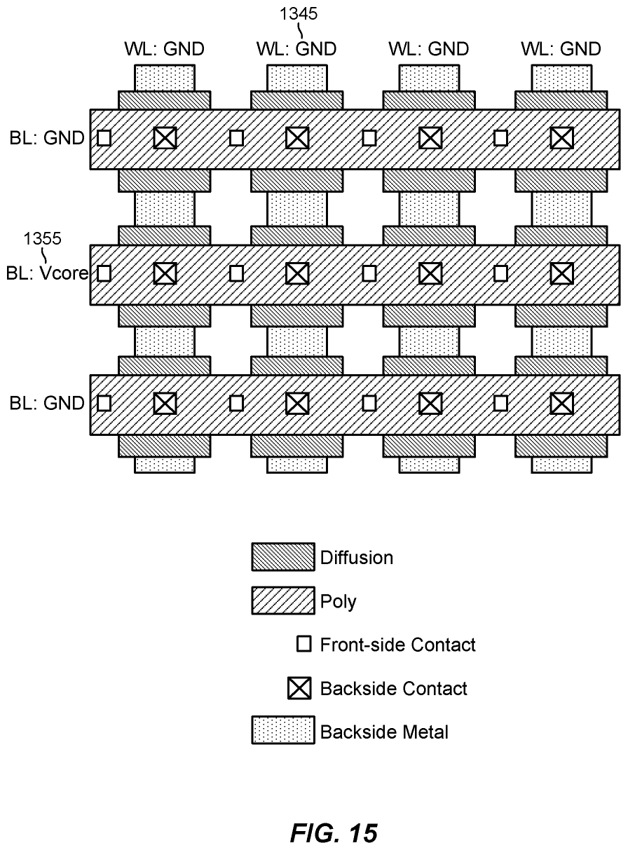

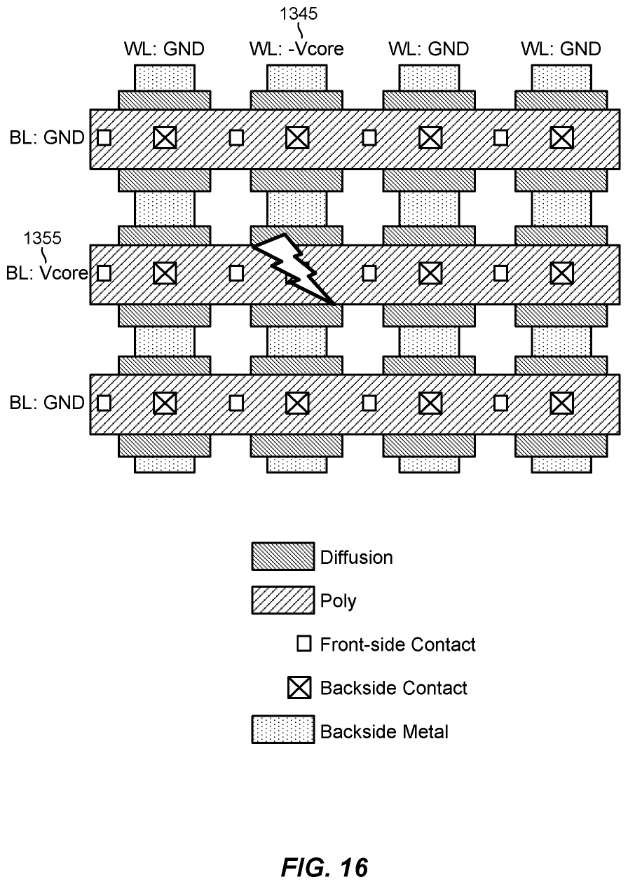

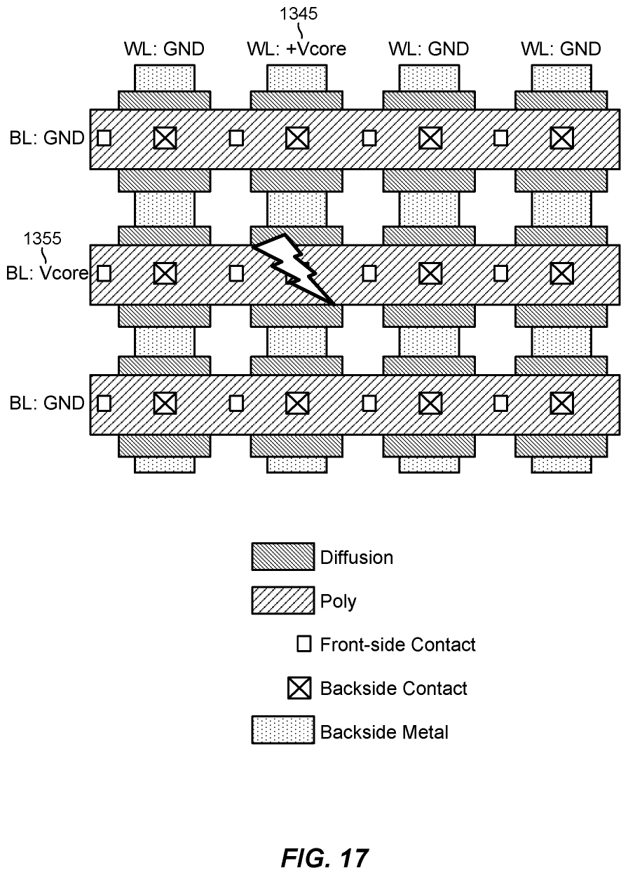

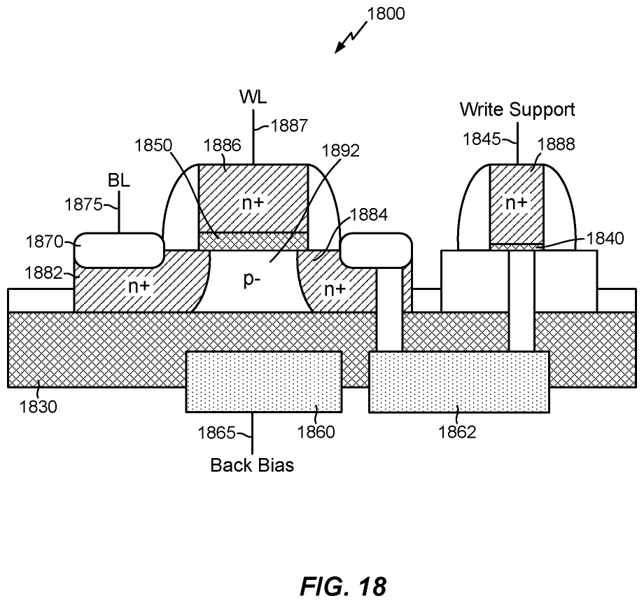

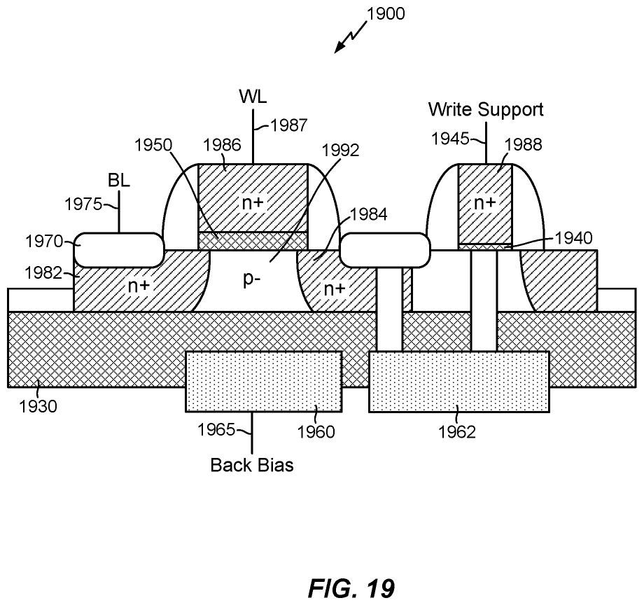

FIGS. 14-17 illustrates an exemplary layout for the antifuse with back side contact of FIG. 13 in accordance with some examples of the disclosure. In a write operation of FIG. 14, the antifuse cell layout 1400 (e.g., a memory device) may have an initial condition with the BL 1355 and the WL 1345 at ground. In the next stage of FIG. 15, write setup, the antifuse cell 1400 may impose 1.2 v (Vcore) on the BL 1355. Then, in the write process of FIG. 16, the antifuse cell 1300 may impose a pulse of 1.2 v (Vcore) on the BL 1355 and −Vcore on the WL 1345. In a read operation of FIG. 17, the antifuse cell 1400 may impose 1.2 v (Vcore) on the WL 1345. Then the current from the BL 1355 may be measured to determine the value of the cell. For example, if no current then the cell is a zero. If a current is detected, the cell is a one.

FIG. 18 illustrates an exemplary antifuse with backside contact and passgate in accordance with some examples of the disclosure. As shown in FIG. 18, to avoid potential problems with the stability of a single-transistor technique, such as the current that the WL has to supply during the read process, a passgate can be utilized as shown. For example, as shown in FIG. 18, an antifuse cell 1800 (e.g., a memory device) may include an oxide layer 1830 (e.g., buried oxide layer), write support 1845, a first dielectric layer 1840, a second dielectric layer 1850 above a backside metal 1860 on a first side (backside) of the oxide layer 1830. The first dielectric 1840 may be approximately 8-25 angstroms thick while the second dielectric 1850 may be ten times thicker at approximately 80-250 angstroms and capable of handling approximately 50 amps of current. This may allow more reliable programming with very high margins and low risk at reading. The antifuse cell 1800 may also include a source 1875 (e.g., a BL), a backside bias source 1865, and a source 1887 (e.g., WL). The second side (e.g., front side opposite the backside) of the antifuse cell 1800 may also include a first doping region 1882, a second doping region 1884, and a third doping region 1886, a fourth doping region 1888, and a first diffusion region 1892. The use of a backside metal layer (backside metal 1860) to bias the antifuse cell 1800 may ensure that the antifuse cell 1800 is protected by backside bias that is used to increase the Vt and reduce leakage that could result in unintended program.

FIG. 19 illustrates an exemplary antifuse with backside contact and passgate on same diffusion island in accordance with some examples of the disclosure. As shown in FIG. 19, to avoid potential problems with the stability of a single-transistor technique, such as the current that the WL has to supply during the read process, a passgate can be utilized as shown. For example, as shown in FIG. 19, an antifuse cell 1900 (e.g., a memory device) may include an oxide layer 1930 (e.g., buried oxide layer), write support 1945, a first dielectric layer 1940, a second dielectric layer 1950 above a backside metal 1960 on a first side (backside) of the oxide layer 1930. The first dielectric 1940 may be approximately 8-25 angstroms thick while the second dielectric 1950 may be ten times thicker at approximately 80-250 angstroms and capable of handling approximately 50 amps of current. This may allow more reliable programming with very high margins and low risk at reading. The antifuse cell 1900 may also include a source 1975 (e.g., a BL), a backside bias source 1965, and a source 1987 (e.g., WL). The second side (e.g., front side opposite the backside) of the antifuse cell 1900 may also include a first doping region 1982, a second doping region 1984, and a third doping region 1986, a fourth doping region 1988, and a first diffusion region 1992. The use of a backside metal layer (backside metal 1960) to bias the antifuse cell 1900 may ensure that the antifuse cell 1900 is protected by backside bias that is used to increase the Vt and reduce leakage that could result in unintended program.

It will be appreciated that various aspects disclosed herein can be described as functional equivalents to the structures, materials and/or devices described and/or recognized by those skilled in the art. For example, in one aspect, an apparatus may comprise means for performing the functions of the antifuses described herein. In another example, a memory device (e.g., antifuse cell 100, antifuse cell 300, antifuse cell 400, and antifuse cell 700) comprising: an oxide layer (e.g., oxide layer 130, oxide layer 330, oxide layer 430, and oxide layer 730); means for switching a signal (e.g. passgate transistor 110, passgate transistor 310, passgate transistor 410, and passgate transistor 710) on a front side of the oxide layer; means for creating a conductive path (e.g. antifuse device 120, antifuse device 320, antifuse device 420, and antifuse device 710) on the front side of the oxide layer proximate to the means for switching; a pass transistor gate (e.g. passgate gate 165, passgate gate 365, passgate gate 465, and passgate gate 765) on a backside of the oxide layer; and an antifuse gate (e.g. antifuse gate 145, antifuse gate 345, antifuse gate 445, antifuse gate 745) on the front side of the oxide layer.

In still another example, a memory device (e.g., antifuse cell 100, antifuse cell 300, antifuse cell 400, and antifuse cell 700) may comprise: means for switching a signal (e.g. passgate transistor 110, passgate transistor 310, passgate transistor 410, and passgate transistor 710) on a first portion of the memory device; means for creating a conductive path (e.g. antifuse device 120, antifuse device 320, antifuse device 420, and antifuse device 710) on a second portion of the memory device opposite the first portion; a pass transistor gate (e.g. passgate gate 165, passgate gate 365, passgate gate 465, and passgate gate 765) on a back side of the memory device; an antifuse gate (e.g. antifuse gate 145, antifuse gate 345, antifuse gate 445, antifuse gate 745) on a front side of the memory device opposite the back side; and means for biasing (e.g., protection bias 364, protection bias 464, and protection bias 764) on the back side of the memory device proximate to the pass transistor gate. It will be appreciated that the aforementioned aspects are merely provided as examples and the various aspects claimed are not limited to the specific references and/or illustrations cited as examples.

One or more of the components, processes, features, and/or functions illustrated in FIGS. 1-19 may be rearranged and/or combined into a single component, process, feature or function or incorporated in several components, processes, or functions. Additional elements, components, processes, and/or functions may also be added without departing from the disclosure. It should also be noted that FIGS. 1-19 and its corresponding description in the present disclosure is not limited to dies and/or ICs. In some implementations, FIGS. 1-19 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof

Nothing stated or illustrated depicted in this application is intended to dedicate any component, action, feature, benefit, advantage, or equivalent to the public, regardless of whether the component, action, feature, benefit, advantage, or the equivalent is recited in the claims.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or a plurality of claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well- known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A memory device comprising:
an oxide layer;
a pass transistor on a front side of the oxide layer;
an antifuse device on the front side of the oxide layer proximate to the pass transistor;
a pass transistor gate on a backside of the oxide layer; and
an antifuse gate on the front side of the oxide layer.

2. The memory device of claim 1, wherein the pass transistor gate comprises a metal.

3. The memory device of claim 1, further comprising:
a first dielectric embedded in the oxide layer on the pass transistor gate; and
a second dielectric on the front side of the oxide layer, wherein the second dielectric is a smaller thickness than the first dielectric.

4. The memory device of claim 3, wherein the first dielectric is approximately 10 times larger in thickness than the second dielectric.

5. The memory device of claim 3, wherein the first dielectric is approximately 250 angstroms and the second dielectric is approximately 8-25 angstroms.

6. The memory device of claim 1, further comprising a metal gate on the backside of the oxide layer proximate to the pass transistor gate, wherein the metal gate is coupled to a bias voltage and configured to positively bias the antifuse device during a programming phase.

7. The memory device of claim 1, further comprising:
a first doped region on the front side of the oxide layer;
a first diffusion region on the front side of the oxide layer proximate the first doped region;
a second doped region on the front side of the oxide layer proximate the first diffusion region;
a second diffusion region on the front side of the oxide layer proximate the second doped region; and
a third doped region on the front side of the oxide layer proximate the second diffusion region.

8. The memory device of claim 7, wherein the first doped region comprises an N+ doped region; the first diffusion region comprises a P doped region; the second doped region comprises an N+ doped region; the second diffusion region comprises an N+ or P doped region; and the third doped region comprises an N+, P, or nothing doped region.

9. The memory device of claim 7, further comprising:
a first contact on the first doped region;
a second contact on the antifuse gate; and
a third contact on the third doped region.

10. A memory device comprising:
an oxide layer;
means for switching a signal on a front side of the oxide layer;
means for creating a conductive path on the front side of the oxide layer proximate to the means for switching;
a pass transistor gate on a backside of the oxide layer; and
an antifuse gate on the front side of the oxide layer.

11. The memory device of claim 10, wherein the pass transistor gate comprises a metal.

12. The memory device of claim 10, further comprising:
a first dielectric embedded in the oxide layer on the pass transistor gate; and
a second dielectric on the front side of the oxide layer, wherein the second dielectric is a smaller thickness than the first dielectric.

13. The memory device of claim 12, wherein the first dielectric is approximately 10 times larger in thickness than the second dielectric.

14. The memory device of claim 12, wherein the first dielectric is approximately 250 angstroms and the second dielectric is approximately 8-25 angstroms.

15. The memory device of claim 10, further comprising a metal gate on the backside of the oxide layer proximate to the pass transistor gate, wherein the metal gate is coupled to a bias voltage and configured to positively bias the means for creating the conductive path during a programming phase.

16. The memory device of claim 10, further comprising:
a first doped region on the front side of the oxide layer;
a first diffusion region on the front side of the oxide layer proximate the first doped region;
a second doped region on the front side of the oxide layer proximate the first diffusion region;
a second diffusion region on the front side of the oxide layer proximate the second doped region; and
a third doped region on the front side of the oxide layer proximate the second diffusion region.

17. The memory device of claim 16, wherein the first doped region comprises an N+ doped region; the first diffusion region comprises a P doped region; the second doped region comprises an N+ doped region; the second diffusion region comprises an N+ or P doped region; and the third doped region comprises an N+, P, or nothing doped region.

18. The memory device of claim 16, further comprising:
a first contact on the first doped region;
a second contact on the antifuse gate; and
a third contact on the third doped region.

19. A memory device comprising:
a pass transistor on a first portion of the memory device;
an antifuse device on a second portion of the memory device opposite the first portion;
a pass transistor gate on a back side of the memory device;
an antifuse gate on a front side of the memory device opposite the backside side; and
a bias gate on the back side of the memory device proximate to the pass transistor gate.

20. The memory device of claim 19, wherein the pass transistor gate comprises a metal.

21. The memory device of claim 19, further comprising:
an oxide layer between the antifuse gate and the bias gate;
a first dielectric embedded in the oxide layer on the pass transistor gate; and
a second dielectric on the front side of the memory device, wherein the second dielectric is a smaller thickness than the first dielectric.

22. The memory device of claim 21, wherein the first dielectric is approximately 10 times larger in thickness than the second dielectric.

23. The memory device of claim 21, wherein the first dielectric is approximately 250 angstroms and the second dielectric is approximately 8-25 angstroms.

24. The memory device of claim 19, wherein the bias gate is coupled to a bias voltage and configured to positively bias the antifuse device during a programming phase.

25. The memory device of claim 19, further comprising:
a first doped region on the front side of the memory device;
a first diffusion region on the front side of the memory device proximate the first doped region;
a second doped region on the front side of the memory device proximate the first diffusion region;
a second diffusion region on the front side of the memory device proximate the second doped region; and
a third doped region on the front side of the memory device proximate the second diffusion region.

26. The memory device of claim 25, wherein the first doped region comprises an N+ doped region; the first diffusion region comprises a P doped region; the second doped region comprises an N+ doped region; the second diffusion region comprises an N+ or P doped region; and the third doped region comprises an N+, P, or nothing doped region.

27. The memory device of claim 25, further comprising:
a first contact on the first doped region;
a second contact on the antifuse gate; and
a third contact on the third doped region.

28. A memory device comprising:
means for switching a signal on a first portion of the memory device;
means for creating a conductive path on a second portion of the memory device opposite the first portion;
a pass transistor gate on a back side of the memory device;
an antifuse gate on a front side of the memory device opposite the back side; and
means for biasing on the back side of the memory device proximate to the pass transistor gate.

29. The memory device of claim 28, wherein the means for biasing is coupled to a bias voltage and configured to positively bias the antifuse device during a programming phase.

30. The memory device of claim 28, further comprising:
an oxide layer between the antifuse gate and the means for biasing;
a first dielectric embedded in the oxide layer on the pass transistor gate; and
a second dielectric on the front side of the memory device, wherein the second dielectric is a smaller thickness than the first dielectric.
